(19) United States
(12) Patent Application Publication
(10) Pub. No.: US 2008/0067641 A1
(43) Pub. Date: Mar. 20, 2008

(54) Package semiconductor and fabrication method thereof

(76) Inventor: En-Min Jow, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/592,214

(22) Filed: Nov. 3, 2006

(30) Foreign Application Priority Data
Sep. 15, 2006 (TW) 095134271
Oct. 17, 2006 (TW) 095218331

(51) Int. Cl. H01L 23/495; H01L 21/00

(52) U.S. Cl. 257/666; 257/787; 257/E23.039; 438/123

(57) ABSTRACT

A package structure of semiconductor includes a lead frame, at least one chip, a controlling component and a passive component. Wherein, the controlling component and the chip are configured on the die pad of the lead frame, and encapsulating glue is encapsulated the lead frame, the chip and controlling component to form a packaging body. The encapsulating body is formed at least one cavity, and the depth of the cavity is reached to the surface of the die pad of the lead frame. The passive component is electrically connected to the lead frame inside the cavity.

### BACKGROUND OF THE INVENTION

1. Field of the Invention

The present invention relates to the package structure of semiconductor and the fabrication method, and more especially, to the package structure of semiconductor having a cavity and it's fabrication method.

2. Description of the Prior Art

The semiconductor packaging method, for example, thin small outline package (TSOP), micro small outline package (MSOP) or quarter small outline package (QSOP), is applied to fabricate a memory device or a memory card for the consuming electronic products.

FIG. 1 is a cross-sectional diagram illustrating the conventional package structure of a semiconductor. A lead frame 100 is configured with a controlling component 200, a flash memory chip 300 and a passive component 400 in sequence. Next, an encapsulating glue 500 is used to seal and form a packaging body. Finally, the packaging body is tested to be a good product or a failed one by electrical testing.

Accordingly, due to the packaging body sealed in one-piece structure, the encapsulating glue 500 encapsulates the controlling component 200, the flash memory chip 300 and the passive component 400 together, and then the electrical testing is performed.

On one hand, the root causes of the failure of the electrical testing from the IC components in advance or during packaging process are difficultly identified. It means the electrical testing just only performs after packaging. Once the testing result is failed, the whole packaging materials are scraped, so as to cause the production cost and waste time.

On the other hand, due to packaging body is encapsulated by the encapsulating glue, when the failure of the packaging body is failed, it is hard to investigate the root cause inside the packaging body so as to affect the production yields. Currently, how to overcome the questions hereinabove is a necessary and urgent issue for most manufacturers.

### SUMMARY OF THE INVENTION

In order to avoid the failure of the electrical testing, a packaging body is configured with a passive component, wherein a cavity in the packaging body is formed during encapsulating process for the electrical testing in advance, and the passive component is only set on good packaging body.

In order to investigate the connecting status of a passive component, a cavity of the packaging glue is formed that exposing the partial surface of a lead frame or a substrate to configure a passive component during packaging process.

To achieve the objects mentioned above, one embodiment of the present invention is to provide a package structure of semiconductor, the structure includes; at least one lead frame constituted with a plurality of inner leads, a plurality of outer leads and at least one die pad; at least one chip configured at the die pad of the lead frame; at least one controlling component configured at the die pad of the lead frame; an encapsulating glue encapsulating the lead frame, the chip, the inner leads and the controlling component, wherein the encapsulating glue setting at least one cavity, and the cavity located at any position thereon that exposing the partial surface of the lead frame; at least one passive component configured at the surface of the lead frame in the cavity, and the passive component electrically connected to the lead frame.

To achieve the objects mentioned above, one embodiment of the present invention is to provide the fabricating method of packaging semiconductor. The fabricating method includes the steps of: providing a lead frame; providing at least one flash memory chip and at least one controlling component connected to a die pad of the lead frame; encapsulating a plurality of inner leads of the lead frame, the die pad, the flash memory chip and the controlling component by an encapsulating glue and forming at least one cavity; and setting a passive component at the lead frame of the cavity to electrically connect to the lead frame.

### BRIEF DESCRIPTION OF THE DRAWINGS

FIG. 1 is a cross-sectional diagram illustrating the conventional semiconductor package structure of a semiconductor.

FIG. 2 is a cross-sectional diagram illustrating a packaging body having a cavity in accordance with an embodiment of the present invention.

FIG. 3 is another cross-sectional diagram illustrating a packaging body having a cavity in accordance with an embodiment of the present invention.

FIG. 4 is a cross-sectional diagram illustrating a packaging body having the symmetry of cavities in accordance with an embodiment of the present invention.

FIG. 5A and FIG. 5B are the process-procedure diagrams illustrating a package method according to the present invention.

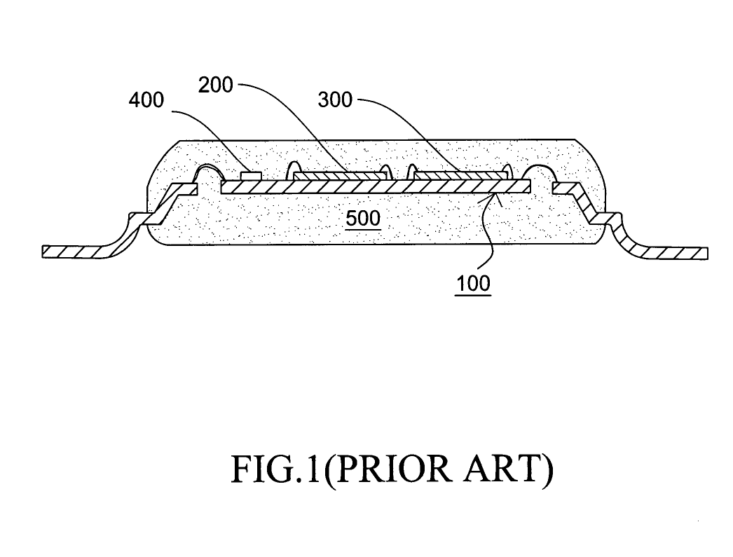

### DESCRIPTION OF THE PREFERRED EMBODIMENT

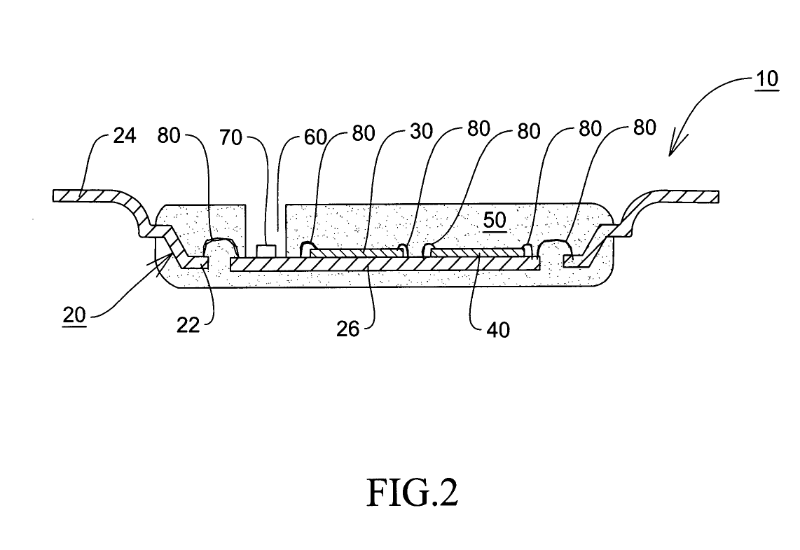

FIG. 2 is a cross-sectional diagram illustrating a packaging body having a cavity in accordance with an embodiment of the present invention. A packaging body 10 has a lead frame 20, a controlling component 30 and a flash memory chip 40. The lead frame 20 includes a plurality of inner leads 22, a plurality of outer leads 24 and a die pad 26. A controlling component 30 and the flash memory chip 40 are positioned on the die pad 26.

The packaging body 10 is encapsulated with an encapsulating glue 50 that encapsulates the controlling component 30, the flash memory chip 40, the inner leads 22 and the die pad 26. The outer leads 24 are not encapsulated by the encapsulating glue 50 and exposed to the outside.

Accordingly, encapsulating glue 50 has an open area to form the cavity 60, and the cavity 60 is formed at any one position of the encapsulating glue 50. Besides, the partial surface of the lead frame 20 is exposed to the cavity for loading the passive component 70, and the passive component 70 is electrically connected to the lead frame 20. The die pad 26 has a plurality of wires 80 that are electrically connected to the inner leads 22, the flash memory chip 40 and the controlling component 30. The encapsulating glue 50 is made of epoxy material, and the lead frame 20 is made of metallic material hereinabove.

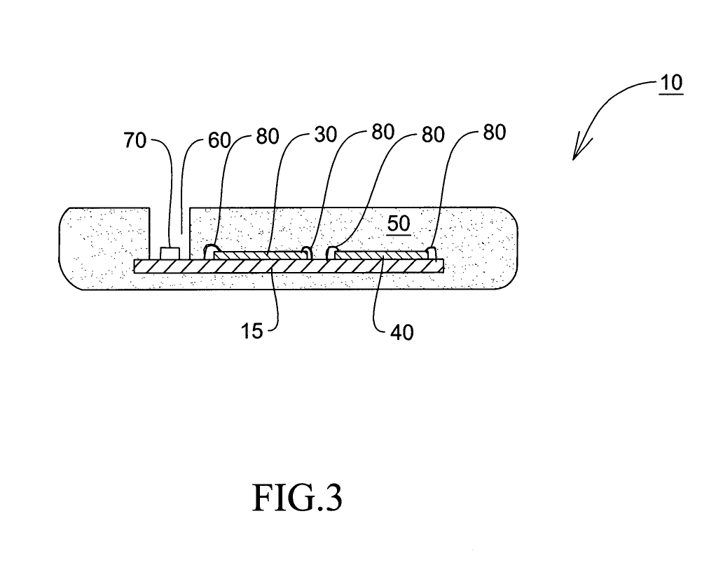

FIG. 3 is another cross-sectional diagram illustrating a packaging body having a cavity in accordance with an embodiment of the present invention. A packaging body 10 has a substrate 15, a controlling component 30 and a flash memory chip 40. A controlling component 30 and the flash memory chip 40 are positioned on the substrate 15.

The packaging body 10 is encapsulated with an encapsulating glue 50 that encapsulates the controlling component 30, the flash memory chip 40, the substrate 15. The partial surface of the substrate 15 are not encapsulated by the encapsulating glue 50 and exposed to the outside.

Accordingly, encapsulating glue 50 has an open area to form the cavity 60, and the cavity 60 is formed at any one position of the encapsulating glue 50. Besides, the partial surface of the substrate 15 is exposed to the cavity 60 for loading the passive component 70, and the passive component 70 is electrically connected to the substrate 15. The substrate 15 has a plurality of wires 80 that are electrically connected to the flash memory chip 40 and the controlling component 30. The encapsulating glue 50 is made of epoxy material hereinabove.

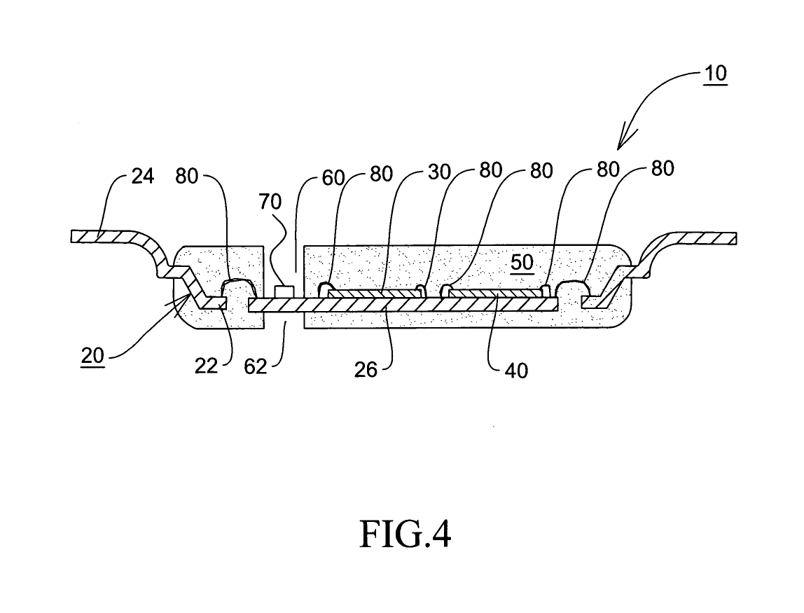

FIG. 4 is another cross-sectional diagram illustrating a packaging body having the symmetry of cavities in accordance with an embodiment of the present invention. The symmetry of the cavities 60 and 62 are formed at the upside and downside side of the packaging body 10 separately, so as to investigate the connecting status of the passive component 70 and the lead frame 20 in the cavity 60 easily. According to the spirits of the present invention, the cavity 60 and 62 of the packaging body 10 are dependent on the demand of the circuit layout, which can be configured with any kind of passive component 70 at any one position in the packaging body 10.

The present invention is applied to all kinds of storing media of electrical products, for example, the digital camera (DC), the personal digital assistance (PDA) or the mobile phone. And the packaging body is manufactured in the secure digital (SD), the multi media card (MMC), the compact flash (CF), the memory stick (MS), the smart media (SM), the xd-picture card (XD), the reduced size multimedia Card (RS-MMC), the mini-secure digital (mini-SD) and the trans flash card.

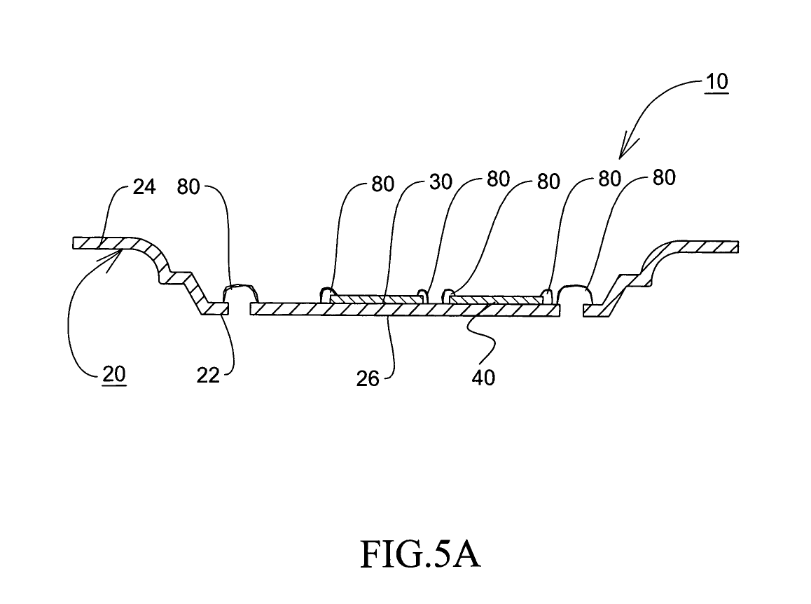

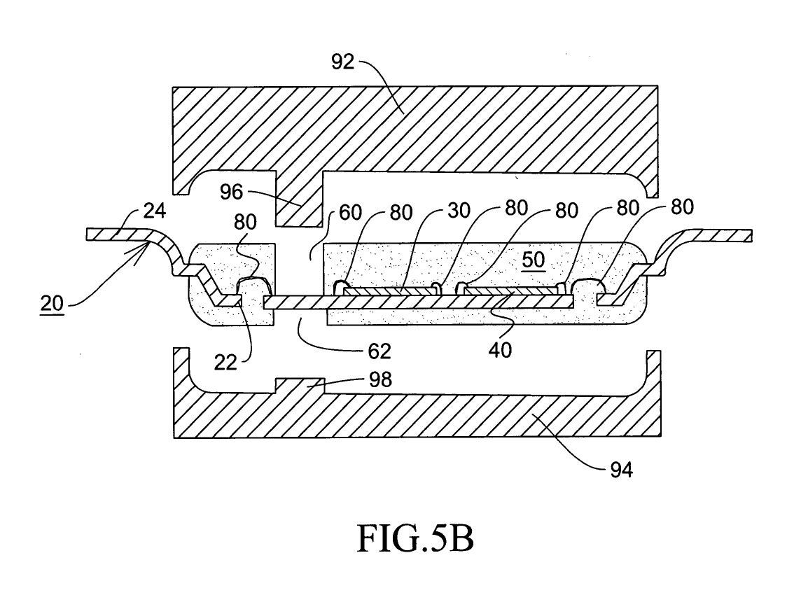

FIG. 5A and FIG. 5B are the process-procedure diagrams illustrating a package method according to the present invention. In FIG. 5A, the lead frame 20 is provided to configure with the controlling component 30 and the flash memory chip 40, the bonding process is utilized at the one end of wire 80 to electrically connect to the inner lead 22, the controlling component 30 and the flash memory chip 40, and another end is connected to the die pad 26.

Next, as shown FIG. 5B, a package molding tool (not shown) is utilized to perform the molding process, that encapsulates the flash memory chip 40 and the controlling component 30 of the packaging body 50, wherein the package molding tool has the structure of a upper mold 92 and a lower mold 94 to be formed with bump 96 and 98.

When the encapsulating process is executed, the bump 96 and 98 are contacted to the upper side and the lower side of the lead frame 20 separately to make the pressing action, and to prevent the encapsulating body 50 being encapsulated totally. Next, the passive component 70 is configured in the cavity 60, and is electrically connected to the lead frame 20, so the completion of the package structure is shown in FIG. 4.

According to the spirit of this invention, the upper mold 92 or lower mold 94 has the single bump 96 to form the cavity 60, and then is configured with the passive component 70 to complete the structure of the packaging body, as shown in FIG. 2.

According to the embodiment expressed above, the completion of the package body is examined by electrical testing. If the test result is an abnormal status, the packaging body is scraped in advance to avoid the prior art's problem, wherein the packaging body packages the controlling component, the flash memory chip and the passive component together, then the electrical testing is performed. Therefore, the abnormal packaging body can be scraped in advance to reduce the unnecessary manufacturing time, so the material of the cost is saved.

To sum up, this invention provides a structure of package semiconductor and fabrication method thereof, which utilize the encapsulating glue to form the cavity for configuring with the passive component. And, the packaging body may perform the electrical testing in advance, after passing the electrical testing the passive components can be configured to continue the later processes. So the failed packaging body avoids from configuring with the passive component, and the passive component in the cavity is investigated for the connecting status, and analyzed. The root cause of the failed packaging body can be checked easily.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A package structure of semiconductor, comprising:
at least one lead frame constituted with a plurality of inner leads, a plurality of outer leads and at least one die pad;
at least one chip configured at said die pad of said lead frame;
at least one controlling component configured at said die pad of said lead frame;
an encapsulating glue encapsulating said lead frame, said chip, said inner leads and said controlling component, wherein said encapsulating glue is set at least one cavity, and said cavity is located at any position thereon that exposing the partial surface of said lead frame; and
at least one passive component configured at the surface of said lead frame in said cavity, and said passive component electrically connected to said lead frame.

2. The package structure of semiconductor according to claim 1, wherein said chip is a flash memory chip.

3. The package structure of semiconductor according to claim 1, wherein said encapsulating glue is made of epoxy.

4. The package structure of semiconductor according to claim 1, wherein said lead frame is made of metallic material.

5. The package structure of semiconductor according to claim 1, wherein said outer leads are exposed to outside of said encapsulating glue.

6. The package structure of semiconductor according to claim 1, wherein said die pad is configured with a plurality of wires to electrically connect to said inner leads, said chip and said controlling component.

7. The package structure of semiconductor according to claim 1, wherein said packaging structure is applied to a storage memory of an electronic product, that is a digital camera (DC), a personal digital assistance (PDA) or a mobile phone.

8. The package structure of semiconductor according to claim 1, wherein said package structure is applied to a memory card that is the secure digital (SD), the multi media card (MMC), the compact flash (CF), the memory stick (MS), the smart media (SM), the xd-picture card (XD), the reduced size multimedia card (RS-MMC), the mini-secure digital (mini-SD) or the trans flash card.

9. A package structure of semiconductor, comprising:
at least one lead frame constituted with a plurality of inner leads, a plurality of outer leads and at least one die pad;
at least one chip configured at said die pad of said lead frame;
at least one controlling component configured at said die pad of said lead frame;
an encapsulating glue encapsulating with said lead frame, said chip, said inner leads and said controlling component, wherein said encapsulating glue is set a plurality of cavities, and said cavities located at any position thereon that exposing the partial surface of said lead frame; and
at least one passive component configured at the surface of said lead frame in said cavity, and said passive component electrically connected to said lead frame.

10. The package structure of semiconductor according to claim 9, wherein said chip is a flash memory chip.

11. The package structure of semiconductor according to claim 9, wherein said encapsulating glue is made of epoxy.

12. The package structure of semiconductor according to claim 9, wherein said lead frame is made of metallic material.

13. The package structure of semiconductor according to claim 9, wherein said outer leads are exposed to outside of said encapsulating glue.

14. The package structure of semiconductor according to claim 9, wherein said die pad is configured with a plurality of wires to electrically connect to said inner leads, said chip and said controlling component.

15. The package structure of semiconductor according to claim 9, wherein said package structure is applied to a storage memory of an electronic product that is a digital camera (DC), a personal digital assistance (PDA) or a mobile phone.

16. The package structure of semiconductor according to claim 9, wherein said package structure is applied to a memory card that is the secure digital (SD), the multi media card (MMC), the compact flash (CF), the memory stick (MS), the smart media (SM), the xd-picture card (XD), the reduced size multimedia card (RS-MMC), the mini-secure digital (mini-SD) and the trans flash card.

17. A package structure of semiconductor, comprising:
a substrate;
at least one chip configured at said substrate;
at least one controlling component configured at said substrate;
an encapsulating glue encapsulating said substrate, said chip, and said controlling component, wherein said encapsulating glue is set at least one cavity, and said cavity located at any position thereon that exposing the partial surface of said substrate; and
at least one passive component configured at the surface of said substrate in said cavity, and said passive component electrically connected to said substrate.

18. The package structure of semiconductor according to claim 17, wherein said chip is a flash memory chip.

19. The package structure of semiconductor according to claim 17, wherein said encapsulating glue is made of epoxy.

20. The package structure of semiconductor according to claim 17, wherein said encapsulating glue exposes the partial surface of said substrate.

21. The package structure of semiconductor according to claim 17, wherein said die pad is configured with a plurality of wires to electrically connect to said substrate, said chip and said controlling component.

22. The package structure of semiconductor according to claim 17, wherein said packaging structure is applied to a storage memory of an electronic product, that is a digital camera (DC), a personal digital assistance (PDA) or a mobile phone.

23. The package structure of semiconductor according to claim 17, wherein said package structure is applied to a memory card, that is the secure digital (SD), the multi media card (MMC), the compact flash (CF), the memory stick (MS), the smart media (SM), the xd-picture card (XD), the reduced size multimedia card (RS-MMC), the mini-secure digital (mini-SD) or the trans flash card.

24. The package method of semiconductor comprising the steps of:
providing a lead frame;
providing at least one flash memory chip and at least one controlling component connected to a die pad of said lead frame;
encapsulating a plurality of inner leads of said lead frame, said die pad, said flash memory chip and said controlling component by a encapsulating glue and forming at least one cavity; and
setting a passive component at said lead frame of said cavity to electrically connect to said lead frame.

25. The package method of semiconductor according to claim 24, wherein before said encapsulating step, a bonding process is utilized with a plurality of wires, each that has one end is electrically connected to said inner lead, said controlling component and said flash memory chip separately, and another end connected to said die pad.

26. The package method of semiconductor according to claim 24, wherein said die pad of said lead frame, said inner leads and said controlling component are utilized in a mold to encapsulate thereby, and said encapsulating glue is filled in said mold.

27. The package method of semiconductor according to claim 26, wherein said mold has at least one bump for forming said cavity in said encapsulating glue.
